(19) United States
(12) Patent Application Publication
(10) Pub. No.: US 2012/0146096 A1
(43) Pub. Date: Jun. 14, 2012

(54) NITRIDE BASED SEMICONDUCTOR DEVICE AND METHOD FOR MANUFACTURING THE SAME

(75) Inventors: Younghwan PARK, Seoul (KR); Kiyeol PARK, Gyeonggi-do (KR); Woochul JOEN, Gyeonggi-do (KR)

(73) Assignee: SAMSUNG ELECTRO-MECHANICS CO., LTD.

(21) Appl. No.: 13/049,625

(22) Filed: Mar. 16, 2011

(30) Foreign Application Priority Data
Dec. 9, 2010 (KR) 10-2010-0125285

(51) Int. Cl. H01L 29/778; H01L 21/338

(52) U.S. Cl. 257/194; 438/172; 257/E29.246; 257/E21.403

(57) ABSTRACT

Disclosed herein is a nitride based semiconductor device. There is provided a nitride based semiconductor device according to the exemplary embodiment of the present invention including: a base substrate, an epitaxial growth layer disposed on the base substrate and generating 2-dimensional electron gas (2DEG) therein, and an electrode structure disposed on the epitaxial growth layer and having an extension extending into the epitaxial growth layer to contact the 2-dimensional electron gas.

### CROSS REFERENCE(S) TO RELATED APPLICATIONS

This application claims the benefit under 35 U.S.C. Section 119 of Korean Patent Application Serial No. 10-2010-0125285, entitled “Nitride Based Semiconductor Device And Method For Manufacturing The Same” filed on Dec. 9, 2010, which is hereby incorporated by reference in its entirety into this application.

### BACKGROUND OF THE INVENTION

1. Technical Field

The present invention relates to a nitride based semiconductor device and a method for manufacturing the same, and more particularly, to a nitride based semiconductor device and a method for manufacturing the same capable of being operated at a low turn-on voltage and increasing a forward current amount.

2. Description of the Related Art

A schottky diode among semiconductor devices is a device using a schottky contact that is a junction of a metal and a semiconductor. As the schottky diodes, there is a nitride based semiconductor device using 2-dimensional electron gas (2DEG) as a current moving channel. The nitride based semiconductor device has a base substrate such as a sapphire substrate, an epitaxial growth layer disposed on the base substrate, and a schottky electrode and an ohmic electrode disposed on the epitaxial growth layer. Generally, the schottky electrode is used as an anode and the ohmic electrode is used as a cathode.

However, the nitride based semiconductor schottky diode having the above structure has a trade-off relationship between satisfying low turn-on voltage and low turn-off current and increasing reverse leakage current. Therefore, it is very difficult to implement a technical of increasing a forward current amount at low turn-on voltage without causing reverse leakage current, in a general nitride based semiconductor device.

### SUMMARY OF THE INVENTION

An object of the present invention is to provide a nitride based semiconductor device capable of being operated at low turn-on voltage.

Another object of the present invention is to provide a nitride based semiconductor device with increased forward current amount.

Another object of the present invention is to provide a nitride based semiconductor device capable of being operated at low turn-on voltage.

Another object of the present invention is to provide a method for manufacturing a nitride based semiconductor device capable of increasing forward current amount.

According to an exemplary embodiment of the present invention, there is provided a nitride based semiconductor device, including: a base substrate; an epitaxial growth layer disposed on the base substrate and generating 2-dimensional electron gas (2DEG) therein; and an electrode structure disposed on the epitaxial growth layer and having an extension extending into the epitaxial growth layer to contact the 2-dimensional electron gas.

The electrode structure may include a schottky electrode schottky-contacting the epitaxial growth layer and the extension is provided in the schottky electrode.

The extension may have an island-shaped transverse section.

The extension may be provided to have a lattice pattern.

The extension may have a ring-shaped transverse section.

The extension may be provided to have an annular ring pattern.

The electrode structure may include an ohmic electrode ohmic-contacting the epitaxial growth layer and the extension may be provided in the ohmic electrode.

The electrode structure may include: a schottky electrode disposed in the central area of the epitaxial growth layer and schottky-contacting the epitaxial growth layer and an ohmic electrode disposed along the edge area of the epitaxial growth layer to have a ring shape surrounding the schottky electrode and ohmic-contacting the epitaxial growth layer.

The electrode structure may include: an ohmic electrode disposed on one side of the epitaxial growth layer and ohmic-contacting the epitaxial growth layer; and a schottky electrode opposite to the ohmic electrode on the other side of the epitaxial growth layer and schottky-contacting the epitaxial growth layer.

According to an exemplary embodiment of the present invention, there is provided a method for manufacturing a nitride based semiconductor device, including: preparing a base substrate; forming an epitaxial growth layer on the base substrate, the epitaxial growth layer generating 2-dimensional electron gas therein; and forming an electrode structure on the epitaxial growth layer, the electrode structure extending into the epitaxial growth layer in order to contact the 2-dimensional electron gas.

The forming of the electrode structure may include: forming a depressing part exposing the 2-dimensional electron gas on the epitaxial growth layer; forming a metal layer covering the epitaxial growth layer on the epitaxial growth layer while filling the depressing part; and patterning the metal layer.

The forming of the depressing part may include: forming a first depressing part in the central area of the epitaxial growth layer and forming a second depressing part in the edge area of the epitaxial growth layer, wherein the forming of the metal layer includes: forming a schottky electrode schottky-contacting the epitaxial growth layer while filling the first depressing part in order to contact the 2-dimensional electron gas; and forming an ohmic electrode ohmic-contacting the epitaxial growth layer while filling the second depressing part in order to contact the 2-dimensional electron gas.

The forming of the depressing part may be performed during a mesa process of separating between the nitride based semiconductor devices.

The preparing of the base substrate may include preparing at least any one of a silicon substrate, a silicon carbide substrate, and a sapphire substrate.

The forming of the epitaxial growth layer may include: growing the lower nitride layer on the base substrate by performing an epitaxial growth process using the base substrate as a seed layer; and growing an upper nitride layer having a wider energy band gap than that of the lower nitride layer on the lower nitride layer using the lower nitride layer as a seed layer.

### BRIEF DESCRIPTION OF THE DRAWINGS

FIG. 1 is a plan view showing a nitride based semiconductor device according to an exemplary embodiment of the present invention;

FIG. 2 is a cross-sectional view taken along line I-I′ of FIG. 1;

FIGS. 3A to 3D are diagrams for explaining a detailed operational process of a nitride based semiconductor device according to the exemplary embodiment of the present invention;

FIG. 4 is a flow chart showing a method for manufacturing a nitride based semiconductor device according to the exemplary embodiment of the present invention.

FIGS. 5A to 5D are diagrams for explaining a process of manufacturing the nitride based semiconductor device according to the exemplary embodiment of the present invention;

FIG. 6 is a view showing a modified example of the nitride based semiconductor device according to the exemplary embodiment of the present invention; and

FIG. 7 is a view showing another modified example of the nitride based semiconductor device according to the exemplary embodiment of the present invention.

### DESCRIPTION OF THE PREFERRED EMBODIMENTS

Various advantages and features of the present invention and methods for accomplishing them will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the present specification denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a semiconductor device and a method for manufacturing the same according to exemplary embodiments of the present invention will be described with reference to the accompanying drawings.

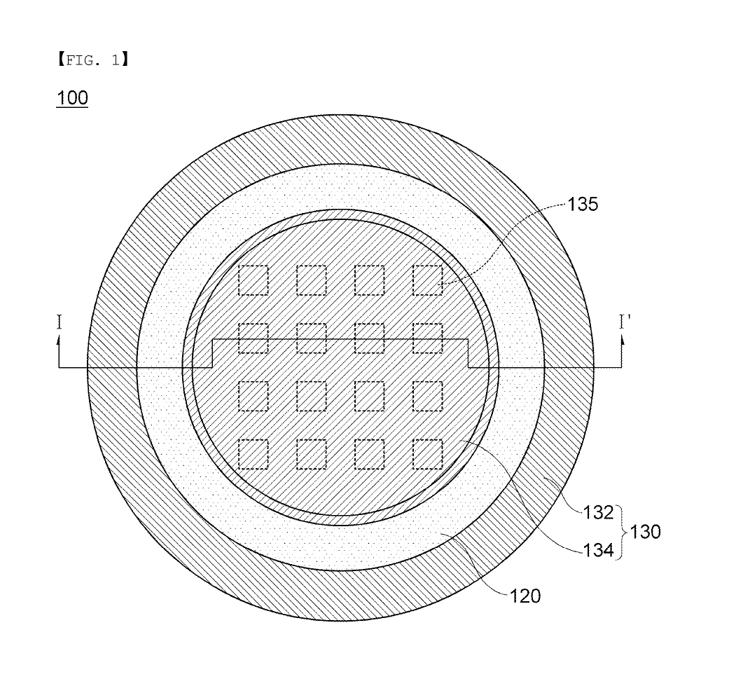

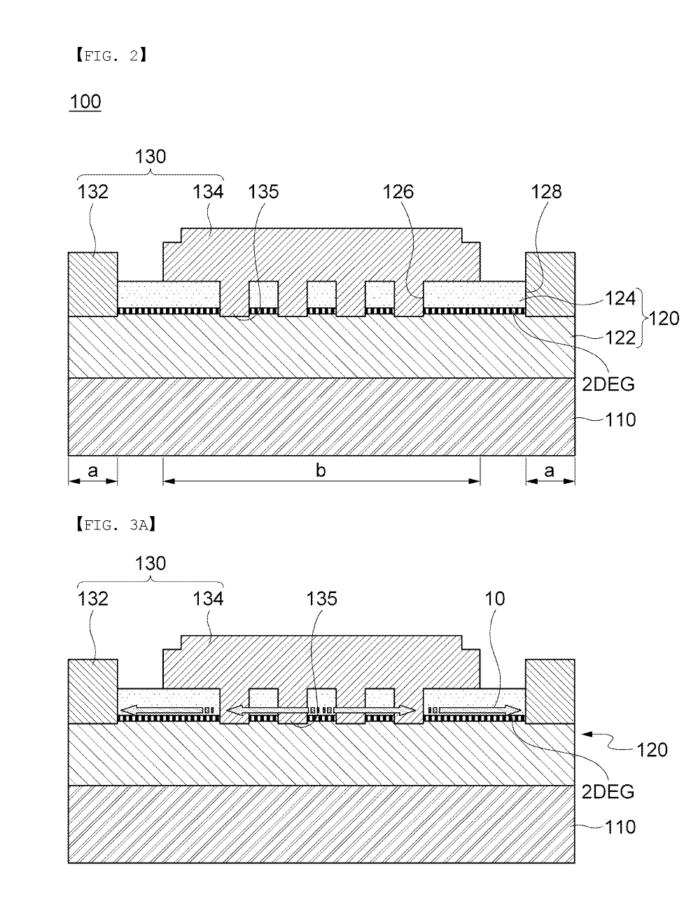

FIG. 1 is a plan view showing a nitride based semiconductor device according to an exemplary embodiment of the present invention and FIG. 2 is a cross-sectional view taken along line I-I′ of FIG. 1.

Referring to FIGS. 1 to 2, a nitride based semiconductor device 100 according to an exemplary embodiment of the present invention may be configured to include a base substrate 110, an epitaxial growth layer 120, and an electrode structure 130.

The base substrate 110 may be a base for forming the epitaxial growth layer 120 and the electrode structure 130. As the base substrate 110, various kinds of substrates may be used. For example, as the base substrate 110, any one of a silicon substrate, a silicon carbide substrate, and a sapphire substrate may be used.

The epitaxial growth layer 120 may be configured to include a lower nitride layer 122 and an upper nitride layer 124 that are sequentially stacked on the base substrate 110. The upper nitride layer 124 may be made of a material having a wider energy band gap than that of the lower nitride layer 122. In addition, the upper nitride layer 124 may be made of a material having a lattice parameter different from that of the lower nitride layer 122. For example, the lower nitride layer 122 and the upper nitride layer 124 may be layers including III-nitride based materials. In more detail, the lower nitride layer 122 may be made of any one of gallium nitride (GaN), aluminum gallium nitride (AlGaN), indium gallium nitride (InGaN), and indium aluminum gallium nitride (InAlGaN), and the upper nitride layer 124 may be made of the other one of gallium nitride (GaN), aluminum gallium nitride (AlGaN), indium gallium nitride (InGaN), and indium aluminum gallium nitride (InAlGaN). As an example, the lower nitride layer 122 may be a gallium nitride (GaN) layer, and the upper nitride layer 124 may be an aluminum gallium nitride (AlGaN) layer.

In the epitaxial growth layer 120, the second-dimensional electron gas (2DEG) may be generated at a boundary between the lower nitride layer 122 and the upper nitride layer 124. At the time of the switching operation of the nitride based semiconductor device 100, current may flow through the second-dimensional electron gas (2DEG).

In this case, a buffer layer (not shown) may be interposed between the base substrate 110 and the epitaxial growth layer 120. The buffer layer may be a layer to reduce the occurrence of defects due to a lattice mismatch between the base substrate 110 and the epitaxial growth layer 120. To this end, the buffer layer may have a super-lattice layer structure in which thin films made of heterogeneous materials are alternately stacked. The super-lattice layer may have a multi-layer structure in which an insulator layer and a semiconductor layer are alternately grown.

The electrode structure 130 may be disposed on the epitaxial growth layer 120. The electrode structure 130 may have an ohmic electrode 132 and a schottky electrode 134. The ohmic electrode 132 ohmic-contacts the epitaxial growth layer 120 and the schottky electrode 134 may be provided to form the schottky-contact with the epitaxial growth layer 120. The ohmic and schottky electrodes 132 and 134 may be a layer made of various metals. The above-mentioned ohmic electrode 132 is used as a cathode of the nitride based semiconductor device and the schottky electrode 134 may be an anode of the nitride based semiconductor device 100.

The ohmic electrode 132 may be disposed in an edge area (a) of the epitaxial growth layer 120 and the schottky electrode 134 may be disposed at a central area (b) of the epitaxial growth layer 120. When the epitaxial growth layer 120 has a circular-shaped transverse section, the ohmic electrode 1230 may have a ring shape along the edge area (b) and the schottky electrode 134 may have a shape surrounded by the ohmic electrode 132.

Meanwhile, the electrode structure 130 may have a structure extending into the epitaxial growth layer 120 to contact the 2-dimensional electron gas (2DEG). For example, the schottky electrode 134 may have an extension 135 extending into the epitaxial growth layer 120 to contact the 2-dimensional electron gas (2DEG). To this end, the epitaxial growth layer 120 may have a first depressing part 126 where the extension 135 is disposed. The first depressing part 126 may be a groove exposing the lower nitride layer 122 on the central area (b). The schottky electrode 134 having the above-mentioned structure directly contacts the 2-dimensional electron gas (2DEG) defining the current moving path of the nitride based semiconductor device 100, such that it may have a resistance value approaching 0. Therefore, the schottky electrode 134 has electrode characteristics similar to the ohmic contact, such that the nitride based semiconductor device 100 may be operated forward even at the remarkably lower voltage than the schottky electrode that does not contact the 2-dimensional electron gas (2DEG).

Optionally, the ohmic electrode 132 may also have a structure extending into the epitaxial growth layer 120 to contact the 2-dimensional electron gas (2DEG). To this end, the epitaxial growth layer 120 may have a second depressing part 128 where the extension of the ohmic electrode 132 is disposed. The second depressing part 128 may be a groove exposing the lower nitride layer 122 on the edge area (a). The current direction to the ohmic electrode 132 from the schottky electrode 134 is substantially a horizontal direction by the ohmic electrode 132 having the above-mentioned structure, such that the current moving path may be shortened.

Next, a detailed operation process of a nitride based semiconductor device according to an exemplary embodiment of the present invention will be described in detail. In this configuration, the overlapped description of the nitride based semiconductor device 100 described with reference to FIGS. 1 and 2 may be omitted or simplified.

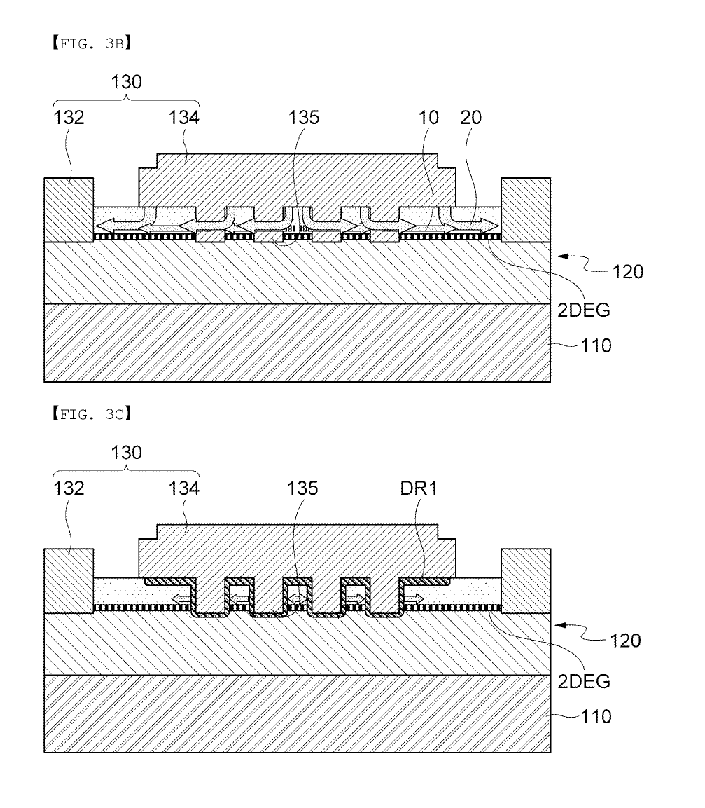

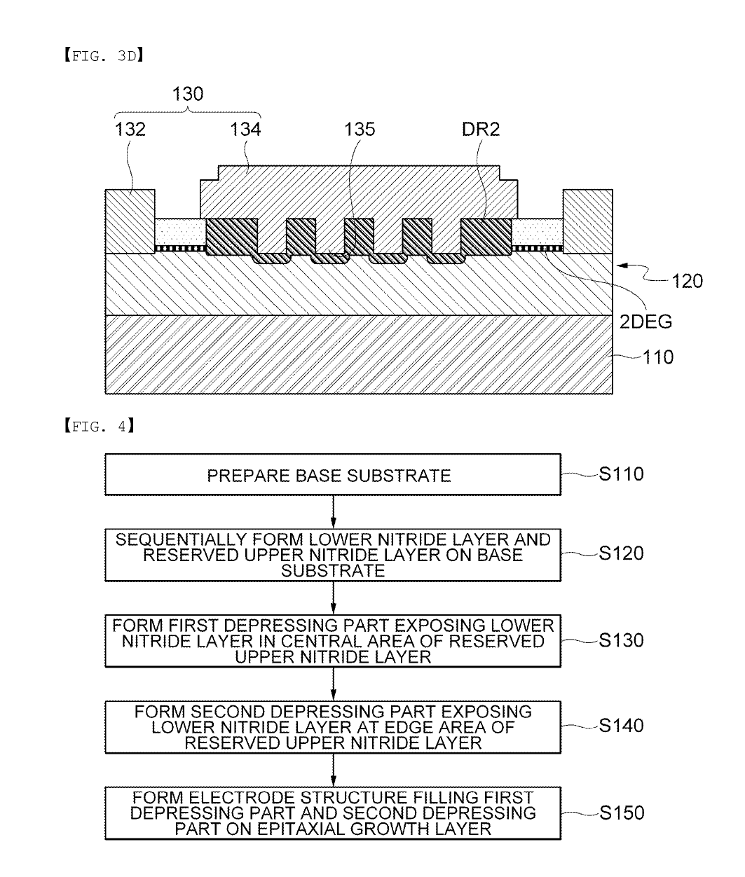

FIGS. 3A to 3D are diagrams for explaining a detailed operational process of a nitride based semiconductor device according to an exemplary embodiment of the present invention. In more detail, FIG. 3A is a diagram showing a current flow when a lower voltage than the turn-on voltage of the schottky electrode is applied, when the nitride based semiconductor device according to the exemplary embodiment of the present invention is driven forward. FIG. 3B is a diagram showing a current flow when a higher voltage than the turn-on voltage of the schottky electrode is applied to the nitride based semiconductor device, when the nitride based semiconductor device according to the exemplary embodiment of the present invention is driven forward. FIGS. 3C and 3D are diagrams for explaining a process of blocking a current flow through the 2-D electron gas by the depletion area of the schottky area by applying a reverse driving voltage to the nitride semiconductor device according to the exemplary embodiment of the present invention.

Referring to FIG. 3A, when the nitride based semiconductor device according to the exemplary embodiment of the present invention is driven forward at the relatively lower voltage than the turn-on voltage of the schottky electrode 134, the current flow from the schottky electrode 134 to the ohmic electrode 132 may be selectively made through a portion contacting the 2-dimensional electron gas (2DEG) of the electrode structure 130. That is, current 10 may flow from the extension 135 of the schottky electrode 134 to the ohmic electrode 132 through the 2-dimensional electron gas (2DEG).

Referring to FIG. 3B, when the nitride based semiconductor device according to the exemplary embodiment of the present invention is driven forward at the higher voltage than the turn-on voltage of the schottky electrode 134, the current may flow from the schottky electrode 134 to the ohmic electrode 132 through the remaining portion, together with a portion contacting the 2-dimensional electron gas (2DEG) of the electrode structure 130. That is, current 20 may flow from the schottky electrode 134 non-contacting the 2-dimensional electron gas (2DEG) to the ohmic electrode 132 through the 2-dimensional electron gas (2DEG), together with the current 10 flowing from the extension 135 to the ohmic electrode 132 as described with reference to FIG. 3A.

Referring to FIG. 3C, when the nitride based semiconductor device according to the exemplary embodiment of the present invention starts to be applied with a voltage at the time of being driven reversely, the current flow from the schottky electrode 134 to the ohmic electrode 132 may be blocked by a depletion region (DR1) caused by the schottky contact of the schottky electrode 134. When the magnitude in the reverse voltage is increased, the current flow may be completely blocked by an expanded depletion area DR2.

As described above, the nitride based semiconductor device 100 according to the exemplary embodiment of the present invention may be configured to include the base substrate 110, the epitaxial growth layer 120 generating the 2-dimensional electron gas (2DEG), and the electrode structure 130 formed on the epitaxial growth layer 120 and having a portion extending into the epitaxial growth layer 120 to directly contact the 2-dimensional electron gas (2DEG). In this case, the schottky electrode 134 of the electrode structure 130 contacts the 2-dimensional electron gas (2DEG) to minimize the current resistance value, such that it may be similarly operated to the ohmic contact. Therefore, the nitride based semiconductor device according to the exemplary embodiment of the present invention moves the current through the portion of the electrode structure contacting the 2-dimensional electron gas when the driving voltage is driven at a lower voltage than the turn-on voltage of the schottky diode at the time of the forward operation and moves current through a contact point between the entire schottky electrode and the 2-dimensional electron gas at the time of being driven at voltage higher than the turn-on voltage, thereby making it possible to increase the forward current amount.

Hereinafter, a method for manufacturing a nitride-based semiconductor device according to an embodiment of the present invention will be described in detail. In this configuration, the overlapped description of the nitride based semiconductor device 100 described with reference to FIGS. 1 and 2 may be omitted or simplified.

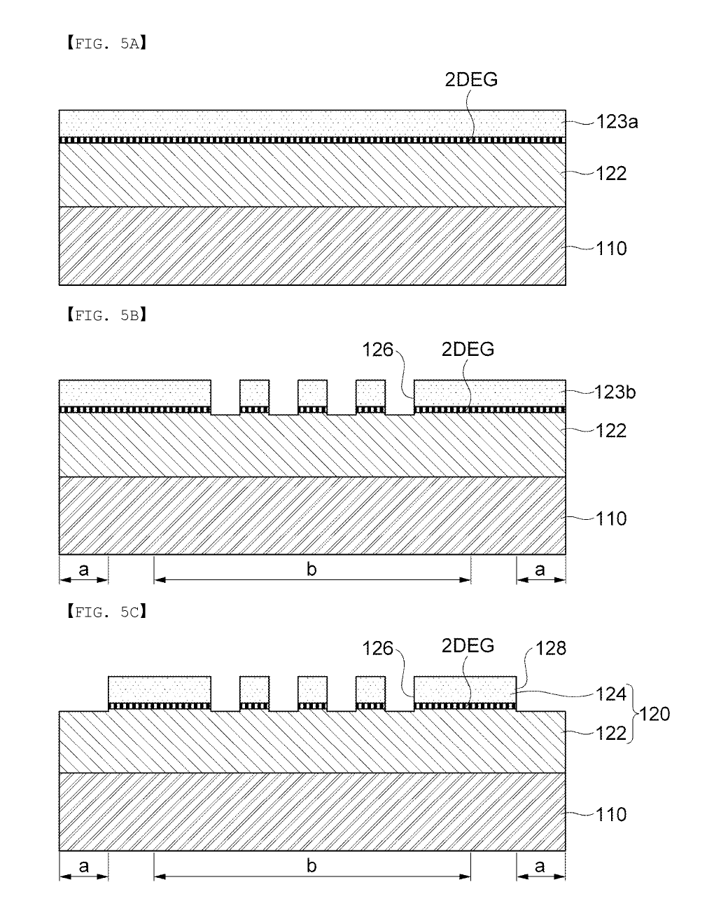

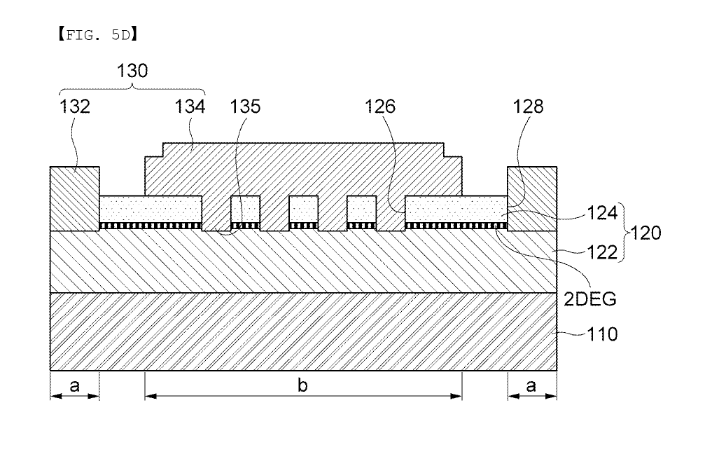

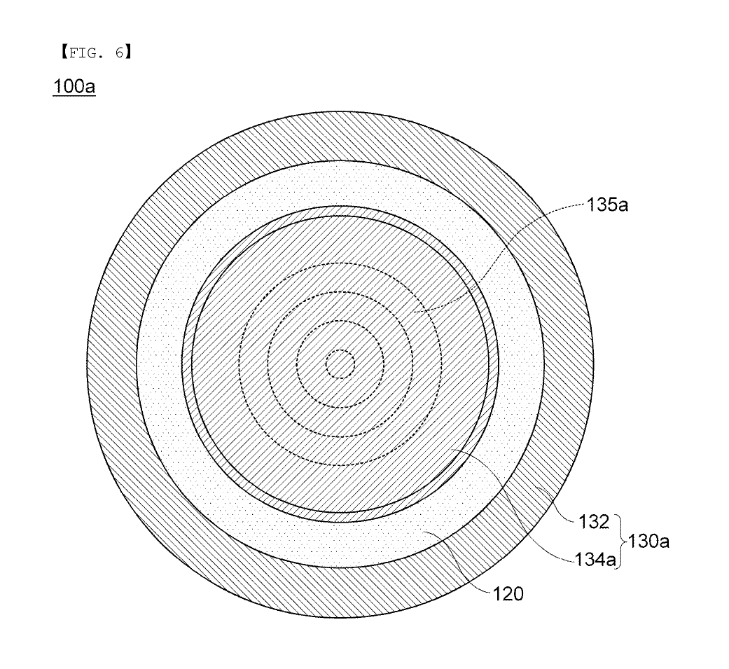

FIG. 4 is a flow chart showing a method for manufacturing a nitride based semiconductor device according to the exemplary embodiment of the present invention. FIGS. 5A to 5D are diagrams for explaining a process of manufacturing the nitride based semiconductor device according to the exemplary embodiment of the present invention.

Referring to FIGS. 4 and 5A, the base substrate 110 may be prepared (S110). For example, the preparing of the base substrate 100 may include preparing any one of a silicon substrate, a silicon carbide substrate, and a sapphire substrate.

A lower nitride layer 122 and a reserved upper nitride layer 123a may be sequentially formed on the base substrate (S120). For example, the lower nitride layer 122 is formed by performing an epitaxial growth process using the base substrate 110 as a seed layer and the reserved upper nitride layer 123a may be formed by performing the epitaxial growth process using the semiconductor layer as a seed layer.

The epitaxial growth process may be a process of growing the semiconductor layer including a III-nitride-based material. As an example, an example of the epitaxial process of forming the lower nitride layer 122 may include a process of forming the gallium nitride (GaN) layer and an example of the epitaxial process of forming the reserved upper nitride layer 123a may include a process of forming the aluminum gallium nitride (AlGaN) layer. In the epitaxial growth layer 120, the second-dimensional electron gas (2DEG) may be generated at a boundary between the lower nitride layer 122 and the reserved upper nitride layer 123a.

Meanwhile, as an epitaxial growth process for forming the epitaxial growth layer 120, at least any one of a molecular beam epitaxial growth process, an atomic layer epitaxial growth process, a flow modulation organometallic vapor phase epitaxial growth process, a flow modulation organometallic vapor phase epitaxial growth process, and a hybrid vapor phase epitaxial growth process may be used.

Referring to FIGS. 4 and 5B, the first depressing part 126 exposing the lower nitride layer 122 may be formed in the central area of the reserved upper nitride layer 123a (S140). As the forming of the first depressing part 126, a photolithography process may be used. For example, the forming of the first depressing part 126 performs an exposure process of forming a photo resist pattern (not shown) exposing the central area (b) on the reserved upper nitride layer 123a and using a photoresist pattern as an etch mask and then, a developing process of selectively removing the reserved upper nitride layer (123a of FIG. 5A) on the central area (b). After the first depressing part 126 is formed, the photoresist pattern may be removed. Therefore, the reserved upper nitride layer 123a having the first depressing part 126 may be formed on the lower nitride layer 122.

In this configuration, since the first depressing part 126 defines the shape of the extension 135 of the schottky electrode (134 of FIG. 5B) later, the forming of the first depressing part 126 may be performed in consideration of the shape of the extension 135. For example, when the extension 135 is formed to have an island-shaped transverse section, the first depressing part 126 may be formed to have the island-shaped transverse surface. In this case, when the extension 135 has a lattice pattern, the first depressing part 126 may also be formed to have the lattice pattern.

Referring to FIGS. 4 and 5C, the second depressing part 128 exposing the lower nitride layer 122 may be formed in the edge area of the reserved upper nitride layer 123a (S130). As the forming of the second depressing part 128, the photolithography process may be used. For example, the forming of the second depressing part 128 performs an exposure process of forming a second photoresist pattern (not shown) exposing the edge area (a) on the epitaxial growth layer 120 and using the second photoresist pattern as the etch mask and then, a developing process of selectively removing the reserved upper nitride layer 123a on the edge area (a). After the second depressing part 128 is formed, the second photoresist pattern may be removed. Therefore, the upper nitride layer 124 having the first and second depressing parts 126 and 128 exposing the lower nitride layer 122 is formed on the base substrate 110, such that the epitaxial growth layer 120 may be formed.

Meanwhile, the exemplary embodiment of the present invention describes, by way of example, the case where the first and second depressing parts 126 and 128 are formed using a predetermined photolithography process, but the first and second depressing parts 126 and 128 may be formed during a mesa process. In more detail, the nitride based semiconductor devices is manufactured in a substrate level state and then, each nitride based semiconductor device may be separate into unit devices by using the mesa process that is a process of electrically separating the devices on the substrate. The mesa process may be performed to form a predetermined trench at a boundary between the nitride based semiconductor devices. The depth of the trench may be controlled to expose the lower nitride layer 122 of the epitaxial growth layer 120. Therefore, since the first and second depressing parts 126 and 128 are formed by using the mesa process used to electrically separate the nitride based semiconductor devices, the method for manufacturing a nitride based semiconductor device according to the exemplary embodiment of the present invention may form the first and second depressing parts 126 and 128 through the mesa process, without additionally performing the process of forming a separate depressing part.

Referring to FIGS. 4 and 5D, the electrode structure 130 filling the first depressing part 126 and the second depressing part 128 may be formed on the epitaxial growth layer 120 (S150). For example, the forming of the electrode structure 130 may include forming a metal layer covering the epitaxial growth layer 120 while filling the first and second depressing parts 126 and 128 on the epitaxial growth layer 120 and patterning the metal layer using the photolithography process. Therefore, the ohmic electrode 132 contacting the 2-dimensional electron gas (2DEG) may be formed on the edge area (a) of the epitaxial growth layer 120. In addition, the schottky electrode 134 contacting the 2-dimensional electron gas (2DEG) may be formed on the central area (b) of the epitaxial growth layer 120.

In this case, the forming of the metal layer effectively fill the metal layer in the first and second depressing units 126 and 128, such that it is performed with an excellent step coverage. For example, the forming of the metal layer may be made by performing any one of chemical vapor deposition (CVD), atomic layer deposition (ALD), ion sputtering, and thermal oxide on the substrate 110. However, the physical vapor deposition (PVD) process may selectively be used as the process of forming a metal layer.

As described above, the method for manufacturing a nitride based semiconductor device according to the exemplary embodiment of the present invention may form the epitaxial growth layer 120 having the first and second depressing parts 126 and 128 exposing the 2-dimensional electron gas (2DEG) on the base substrate 110 and the electrode structure 130 contacting the 2-dimensional electron gas (2DEG) by filling the first and second depressing parts 126 and 128 on the epitaxial growth layer 120. Therefore, the method for manufacturing the nitride based semiconductor device according to the exemplary embodiment of the present invention can form the electrode structure contacting the 2-dimensional electron gas (2DEG) to lower the resistance value, thereby making it possible to increase the forward current amount.

Hereinafter, modified examples of a method for manufacturing a nitride-based semiconductor device according to another exemplary embodiment of the present invention will be described in detail. In this configuration, the overlapped description of the nitride based semiconductor device 100 described with reference to FIGS. 1 and 2 may be omitted or simplified.

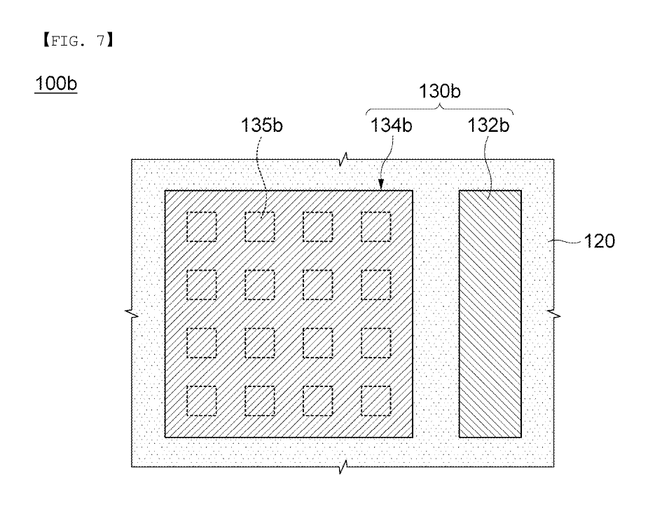

FIG. 6 is a view showing a modified example of the nitride based semiconductor device according to the exemplary embodiment of the present invention. Referring to FIG. 6, a nitride based semiconductor device 100a according to a modified example of the present invention may include an electrode structure 130a having a ring-shaped extension 135a different from the nitride based semiconductor device 100 with reference to FIG. 1.

In more detail, the nitride based semiconductor device 100a includes the electrode structure 130a disposed on the epitaxial growth layer 120 and the electrode structure 130a may include the ohmic electrode 132 and the schottky electrode 134a. The schottky electrode 134a is disposed on the epitaxial growth layer 120, wherein the extension 135a may extend into the epitaxial growth layer 120 to contact the 2-dimensional electron gas (not shown). In this case, the extension 135a may have at least one ring shape. When the extension 135a has a plurality of ring shapes, the extension 135a may be provided to have an annular ring pattern.

FIG. 7 is a view showing another modified example of the nitride based semiconductor device according to the exemplary embodiment of the present invention. Referring to FIG. 7, a nitride based semiconductor device 100b according to a modified example of the present invention may include the electrode structure 130a having a flat-shaped transverse section different from the nitride based semiconductor device 100 with reference to FIG. 1.

In more detail, the nitride based semiconductor device 100a includes the electrode structure 130a disposed on the epitaxial growth layer 120 and the electrode structure 130a may include the ohmic electrode 132b and the schottky electrode 134b having the flat shape. The ohmic electrode 132b is disposed on one area of the epitaxial growth layer 120 and the schottky electrode 134b may be disposed in the other area to be spaced apart from the ohmic electrode 132b. The ohmic electrode 132b may substantially have a bar shape and the schottky electrode 134b may have a flat shape opposite to the ohmic electrode 132b on the epitaxial growth layer 120. In this case, the schottky electrode 134b may have an extension 135b contacting the 2-dimensional electrode gas (not shown) in the epitaxial growth layer 120. In addition, the ohmic electrode 132b may also be configured to contact the 2-dimensional electron gas.

The nitride based semiconductor device according to the exemplary embodiment of the present invention includes the epitaxial growth layer generating the 2-dimensional electron gas therein and the electrode structure disposed on the epitaxial growth layer and extends a portion of the electrode structure into the epitaxial growth layer to contact the 2-dimensional electron gas in order to minimizing a current resistance value through the 2-dimensional electron gas, thereby making it possible to improve the forward current amount.

Further, the nitride based semiconductor device according to the exemplary embodiment of the present invention moves the current through the portion of the electrode structure contacting the 2-dimensional electron gas when the driving voltage is driven at a lower voltage than the turn-on voltage of the schottky diode at the time of the forward operation and moves current through a contact point between the entire schottky electrode and the 2-dimensional electron gas at the time of being driven at voltage higher than the turn-on voltage, thereby making it possible to increase the forward current amount.

The method for manufacturing the nitride based semiconductor device according to the exemplary embodiment of the present invention can form the electrode structure contacting the 2-dimensional electron gas (2DEG) to lower the resistance value, thereby making it possible to increase the forward current amount.

The above detail description is for illustrating the present invention. In addition, the above-described contents is only for showing and explaining preferred embodiment of the present invention, and the present invention may be used in a variety of other combinations, changes, and environments. In other words, modifications or corrections are possible within the scope of concepts of the invention set forth in the present embodiment, the scope of equivalents to written disclosures set forth in the present embodiment and/or the scope of techniques or knowledge in the art. The above-described embodiments are for explaining the best for implementing the present embodiment. Implementation to other forms known in the art and various modifications required in specific application fields and uses of the present invention are possible. Accordingly, the above detailed description of the present invention has no intent to limit the present invention by the presented embodiments. Also, the accompanying claims should be construed to include other embodiments.

What is claimed is:

1. A nitride based semiconductor device, comprising:
a base substrate;
an epitaxial growth layer disposed on the base substrate and generating 2-dimensional electron gas (2DEG) therein; and
an electrode structure disposed on the epitaxial growth layer and having an extension extending into the epitaxial growth layer to contact the 2-dimensional electron gas.

2. The nitride based semiconductor device according to claim 1, wherein the electrode structure includes a schottky electrode schottky-contacting the epitaxial growth layer, and
the extension is provided in the schottky electrode.

3. The nitride based semiconductor device according to claim 2, wherein the extension has an island-shaped transverse section.

4. The nitride based semiconductor device according to claim 3, wherein the extension is provided to have a lattice pattern.

5. The nitride based semiconductor device according to claim 2, wherein the extension has a ring-shaped transverse section.

6. The nitride based semiconductor device according to claim 5, wherein the extension is provided to have an annular ring pattern.

7. The nitride based semiconductor device according to claim 1, wherein the electrode structure includes an ohmic electrode ohmic-contacting the epitaxial growth layer, and
the extension is provided in the ohmic electrode.

8. The nitride based semiconductor device according to claim 1, wherein the electrode structure includes:
a schottky electrode disposed in the central area of the epitaxial growth layer and schottky-contacting the epitaxial growth layer; and
an ohmic electrode disposed along the edge area of the epitaxial growth layer to have a ring shape surrounding the schottky electrode and ohmic-contacting the epitaxial growth layer.

9. The nitride based semiconductor device according to claim 1, wherein the electrode structure includes:
an ohmic electrode disposed on one side of the epitaxial growth layer and ohmic-contacting the epitaxial growth layer; and
a schottky electrode opposite to the ohmic electrode on the other side of the epitaxial growth layer and schottky-contacting the epitaxial growth layer.

10. A method for manufacturing a nitride based semiconductor device, comprising:
preparing a base substrate;
forming an epitaxial growth layer on the base substrate, the epitaxial growth layer generating 2-dimensional electron gas therein; and
forming an electrode structure on the epitaxial growth layer, the electrode structure extending into the epitaxial growth layer in order to contact the 2-dimensional electron gas.

11. The method for manufacturing a nitride based semiconductor device according to claim 10, wherein the forming of the electrode structure includes:
forming a depressing part exposing the 2-dimensional electron gas on the epitaxial growth layer;
forming a metal layer covering the epitaxial growth layer on the epitaxial growth layer while filling the depressing part; and
patterning the metal layer.

12. The method for manufacturing a nitride based semiconductor device according to claim 11, wherein the forming of the depressing part includes:
forming a first depressing part in the central area of the epitaxial growth layer; and
forming a second depressing part in the edge area of the epitaxial growth layer,
wherein the forming of the metal layer includes:
forming a schottky electrode schottky-contacting the epitaxial growth layer while filling the first depressing part in order to contact the 2-dimensional electron gas; and
forming an ohmic electrode ohmic-contacting the epitaxial growth layer while filling the second depressing part in order to contact the 2-dimensional electron gas.

13. The method for manufacturing a nitride based semiconductor device according to claim 11, wherein the forming of the depressing part is performed during a mesa process of separating between the nitride based semiconductor devices.

14. The method for manufacturing a nitride based semiconductor device according to claim 10, wherein the preparing of the base substrate includes preparing at least any one of a silicon substrate, a silicon carbide substrate, and a sapphire substrate.

15. The method for manufacturing a nitride based semiconductor device according to claim 10, wherein the forming of the epitaxial growth layer includes:
growing the lower nitride layer on the base substrate by performing an epitaxial growth process using the base substrate as a seed layer; and
growing an upper nitride layer having a wider energy band gap than that of the lower nitride layer on the lower nitride layer using the lower nitride layer as a seed layer.
